(19) United States
(12) Patent Application Publication
(10) Pub. No.: US 2026/0371825 A1
(43) Pub. Date: Nov. 19, 2026

(54) LIGHT EMITTING DIODE ARRAY SUBSTRATE AND METHOD OF REPAIRING THE SAME

(71) Applicant: AUO Corporation, Hsinchu City (TW)

(72) Inventors: Chia-Hui PAI, Hsinchu City (TW); Wen-Hsien TSENG, Hsinchu City (TW); Chien-Hung KUO, Hsinchu City (TW); Yi-Ta CHEN, Hsinchu City (TW)

(21) Appl. No.: 19/379,324

(22) Filed: Nov. 4, 2025

(30) Foreign Application Priority Data
Mar. 31, 2025 (TW) 114112458

(51) Int. Cl. H10H 29/85; H10H 29/01

(52) U.S. Cl. CPC H10H 29/857; H10H 29/0364

(57) ABSTRACT

A light emitting diode (LED) array substrate is provided. The LED array substrate includes a substrate and at least two LED components. The substrate includes a positive pole (P-pole) region, a negative pole (N-pole) region spaced apart from the P-pole region and at least one floating electrode region spaced apart from the P-pole region and the N-pole region. The P-pole and the N-pole of one of the LED components are connected to the P-pole region and the floating electrode region separately. The P-pole and the N-pole of the other one of the LED components are connected to the floating electrode region and the N-pole region separately. The LED components are connected to each other in series.

### RELATED APPLICATIONS

This application claims priority to Taiwan Application Serial Number 114112458, filed Mar. 31, 2025, which is herein incorporated by reference in its entirety.

### BACKGROUND

### Technical Field

The present disclosure relates to an array substrate device. More particular, the present disclosure relates to a light emitting diode (LED) array substrate.

### Description of Related Art

Generally, there are two types of failed states of LED array substrates. One of the failed states is the open circuit failure due to the damage of the LED components. This failure may be repaired by removing the failed LED component and disposing a new LED component. The other failed state is that the pads on the substrate are contaminated by solders (e.g., the overflow of the soldering paste) during the soldering process of disposing the LED components, resulting in a short circuit failure. This failure should be repaired by removing the contaminants on the pads through methods, such as the short-wave laser micron-scale ablation, so as to eliminate short circuits which are caused by electrical connections between the pads. The aforementioned method can easily damage the components near the pads, resulting in the leakage failure occurs in a certain proportion of the LED components even though the LED array substrate is repaired. Since the two failed states require different repairing methods, it is necessary to determine the failed state of the LED array substrate before repairing, so as to adopt the appropriate repairing method. As a result, the efficiency of repairing the LED array substrate is difficult to be improved.

### SUMMARY

Accordingly, the disclosure is to provide a LED array substrate which is advantage for increasing the efficiency of repairing the LED array substrate.

Furthermore, at least one embodiment of the disclosure is to provide a method of repairing the LED array substrate.

At least one embodiment of the disclosure provides a LED array substrate including a substrate and at least two LED components. The substrate includes a positive pole (P-pole) region, a negative pole (N-pole) region spaced apart from the P-pole region and at least one floating electrode region spaced apart from the P-pole region and the N-pole region. A P-pole and a N-pole of one of the LED components are connected to the P-pole region and the floating electrode region separately, and a P-pole and a N-pole of the other one of the LED components are connected to the floating electrode region and the N-pole region separately. The LED components are connected to each other in series.

At least in one embodiment of the disclosure, the LED array substrate further includes a repairing LED component. A P-pole of the repairing LED component is connected to the P-pole region of the substrate, and a N-pole of the repairing LED component is connected to the N-pole region of the substrate.

At least in one embodiment of the disclosure, the P-pole and the N-pole of the LED components are connected to each other in a first direction, and the P-pole and the N-pole of the repairing LED component are connected to each other in a second direction, wherein the first direction is orthogonal to the second direction.

At least in one embodiment of the disclosure, the P-pole and the N-pole of the LED components are connected to each other in a first direction, and the P-pole and the N-pole of the repairing LED component are connected to each other in a second direction. The first direction is parallel to the second direction.

At least in one embodiment of the disclosure, a light-emitting area of the repairing LED component is an integer multiple of a light-emitting area of each of the LED components, and the light-emitting area of the repairing LED component is at least double the light-emitting area of each of the LED components.

At least in one embodiment of the disclosure, the LED array substrate further includes a pair of pads disposed between the substrate and the repairing LED component. The P-pole of the repairing LED component and the N-pole of the repairing LED component are electrically connected to the P-pole region and the N-pole region of the substrate separately through the pair of pads.

At least in one embodiment of the disclosure, the LED array substrate further includes at least two pairs of pads disposed between the LED components and the substrate. One pair of the pads are located at the P-pole region and the floating electrode region separately, and the other one pair of the pads are located at the floating electrode region and the N-pole region separately.

At least in one embodiment of the disclosure, the LED array substrate further includes at least a soldering material disposed between at least one pair of the pads, and the pair of the pads are electrically connected to each other through the soldering material.

At least in one embodiment of the disclosure, the quantity of the floating electrode region is two, and the P-pole and the N-pole of one of the LED components are connected to the P-pole region and one of the floating electrode regions separately, and the P-pole and the N-pole of the other one of the LED components are connected to the other one of the floating electrode regions and the N-pole region separately. One of the floating electrode regions is electrically connected to the other one of the floating electrode regions.

At least in one embodiment of the disclosure, the quantity of the floating electrode region is three, and the P-pole and the N-pole of at least one of the LED components are connected to two of the floating electrode regions separately.

At least in one embodiment of the disclosure, a first gap is located between the P-pole region and the N-pole region of the substrate, and a second gap is separately located between the floating electrode region and the P-pole region and located between the floating electrode region and the N-pole region. The first gap is larger than the second gap.

At least in one embodiment of the disclosure, the first gap is between 10 μm and 20 μm, and the second gap is between 5 μm and 15 μm.

At least in one embodiment of the disclosure, a quantity of the LED components is N1, and a quantity of the floating electrode regions is N2. The quantity of the LED components and the quantity of the floating electrode regions satisfy the equation N2=N1−1.

At least in one embodiment of the disclosure, the two LED components are substituted by one square type micro LED.

At least one embodiment of the disclosure provides a method of repairing the LED array substrate including providing a failed light emitting diode array substrate. The light emitting diode array substrate includes a substrate and at least two LED components. The substrate includes a P-pole region, a N-pole region spaced apart from the P-pole region and at least one floating electrode region spaced apart from the P-pole region and the N-pole region. A P-pole and a N-pole of one of the LED components are connected to the P-pole region and the floating electrode region separately, and a P-pole and a N-pole of the other one of the LED components are connected to the floating electrode region and the N-pole region separately. The LED components are connected to each other in series, and at least one of the LED components is failed. The method further includes removing the LED components and disposing a repairing LED component on the substrate. A P-pole and a N-pole of the repairing LED component are connected to the P-pole region and the N-pole region of the substrate.

According to the aforementioned embodiments, no matter the failure of the LED array substrate is due to the short of inner components (e.g., the connection of the pads) or due to the open circuit (e.g., the damage of LEDs), the method of repairing the LED array substrate is to disposing the repairing LED component on the substrate. The P-pole and the N-pole of the repairing LED component is connected to the P-pole region and the N-pole region of the substrate separately. Therefore, it is unnecessary to adopt different repairing methods for different failure causes. Thus, the checking step for determining the failure cause of the LED array substrate can be omitted, thereby being advantage to improve the efficiency of repairing the LED array substrate.

### BRIEF DESCRIPTION OF THE DRAWINGS

To illustrate more clearly the aforementioned and the other objects, features, merits, and embodiments of the present disclosure, the description of the accompanying figures are as follows:

FIG. 1 illustrates a schematically top view of a LED array substrate in accordance with at least one embodiment of the present disclosure.

FIG. 2A illustrates a schematically top view of the LED array substrate under one broken circuit state in accordance with at least one embodiment of the present disclosure.

FIG. 2B illustrates a schematically top view of the LED array substrate under another one broken circuit state in accordance with at least one embodiment of the present disclosure.

FIG. 3 illustrates a schematically top view of a LED array substrate in accordance with at least one embodiment of the present disclosure.

FIG. 4 illustrates a schematically top view of a LED array substrate in accordance with at least one embodiment of the present disclosure.

FIG. 5 illustrates a schematically top view of a LED array substrate in accordance with at least one embodiment of the present disclosure.

FIG. 6 illustrates a schematically top view of a LED array substrate in accordance with at least one embodiment of the present disclosure.

FIG. 7A to FIG. 7B illustrate schematically top views of steps of the method of repairing the LED array substrate in accordance with at least one embodiment of present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, the dimensions (such as lengths, widths and thicknesses) of components (such as layers, films, substrates and regions) in the drawings are enlarged not-to-scale, and the number of components may be reduced in order to clarify the technical features of the disclosure. Therefore, the following illustrations and explanations are not limited to the number of components, the number of components, the dimensions and the shapes of components, and the deviation of size and shape caused by the practical procedures or tolerances are included. For example, a flat surface shown in drawings may have rough and/or non-linear features, while angles shown in drawings may be circular. As a result, the drawings of components shown in the disclosure are mainly for illustration and not intended to accurately depict the real shapes of the components, nor are intended to limit the scope of the claimed content of the disclosure.

Further, when a number or a range of numbers is described with “about,” “approximate,” “substantially,” and the like, the term is intended to encompass numbers that are within a reasonable range considering variations that inherently arise during manufacturing as understood by one of ordinary skill in the art. In addition, the number or range of numbers encompasses a reasonable range including the number described, such as within +/−30%, +/−20%, +/−10% or +/−5% of the number described, based on known manufacturing tolerances associated with manufacturing a feature having a characteristic associated with the number. The words of deviations such as “about,” “approximate,” “substantially,” and the like are chosen in accordance with the optical properties, etching properties, mechanical properties or other properties. The words of deviations used in the optical properties, etching properties, mechanical properties or other properties are not chosen with a single standard.

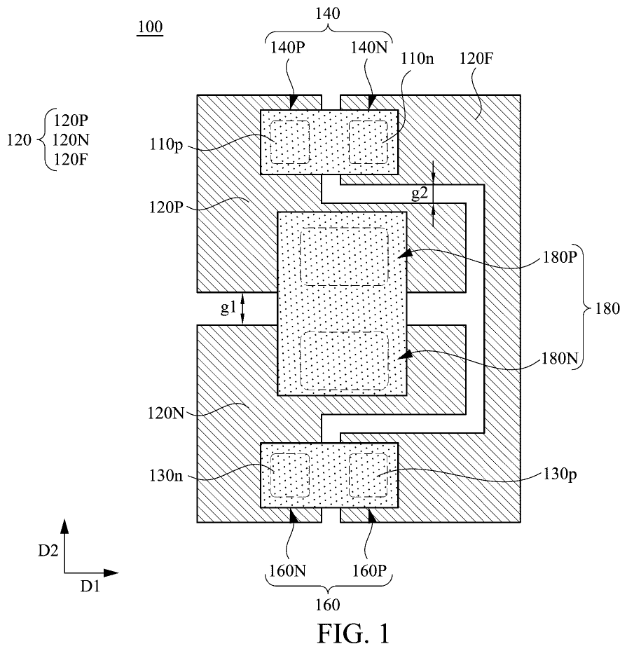

FIG. 1 illustrates a schematically top view of a light emitting diode (LED) array substrate 100 in accordance with one embodiment of the present disclosure. The LED array substrate 100 includes a substrate 120 and at least two LED components, i.e., the LED component 140 and the LED component 160. As shown in FIG. 1, the substrate 120 includes a positive-pole (P-pole) region 120P, a negative-pole (N-pole) region 120N and at least one floating electrode region 120F. The N-pole region 120N is spaced apart from the P-pole region 120P, while the floating electrode region 120F is spaced apart from the P-pole region 120P and the N-pole region 120N.

Specifically, the P-pole region 120P and the N-pole region 120N are disposed at intervals and are not connected to each other. The substrate 120 may include metals, such as copper, nickel, gold, silver, aluminum, cobalt, iron or similar materials.

The P-pole and the N-pole of one of the LED component 140 or the LED component 160 are connected to the P-pole region 120P and the floating electrode region 120F separately, while the P-pole and the N-pole of the other one of the LED component 140 or the LED component 160 are connected to the floating electrode region 120F and the N-pole region 120N separately. Specifically, the P-pole 140P of the LED component 140 is connected to the P-pole region 120P of the substrate 120, while the N-pole 140N of the LED component 140 is connected to the floating electrode region 120F of the substrate 120. In addition, the P-pole 160P of the LED component 160 is connected to the floating electrode region 120F of the substrate 120, while the N-pole 160N of the LED component 160 is connected to the N-pole region 120N of the substrate 120.

It is worth mentioning, the LED component 140 and the LED component 160 are electrically connected to each other in series. That is, when the LED array substrate 100 is under a functional state (i.e., the LED component 140 and the LED component 160 are emitting light), the LED component 140 is electrically connected to the LED component 160 in series.

In addition, the LED array substrate 100 further includes at least two pairs of pads, i.e., the pad 110p, the pad 110n, the pad 130p and the 130n (illustrated by dash lines). These pads are disposed between the LED components (the LED component 140 and the LED component 160) and the substrate 120. Specifically, the pad 110p and the pad 110n are disposed between the LED component 140 and the substrate 120, while the pad 110p and the pad 110n are located at the P-pole region 120P and the floating electrode region 120F of the substrate 120. Further, the P-pole 140P and the N-pole 140N of the LED component 140 are disposed on the pad 110p and the pad 110n separately. That is, the LED component 140 is electrically connected to the P-pole region 120P and the floating electrode region 120F through the pad 110p and the pad 110n.

On the other hand, the pad 130p and the pad 130n are disposed between the LED component 160 and the substrate 120, while the pad 130p and the pad 130n are located at the floating electrode region 120F and the N-pole region 120N of the substrate 120. In addition, the P-pole 160P and the N-pole 160N of the LED component 160 are disposed on the pad 130p and the pad 130n separately. That is, the LED component 160 is electrically connected to the floating electrode region 120F and the N-pole region 120N through the pad 130p and the pad 130n.

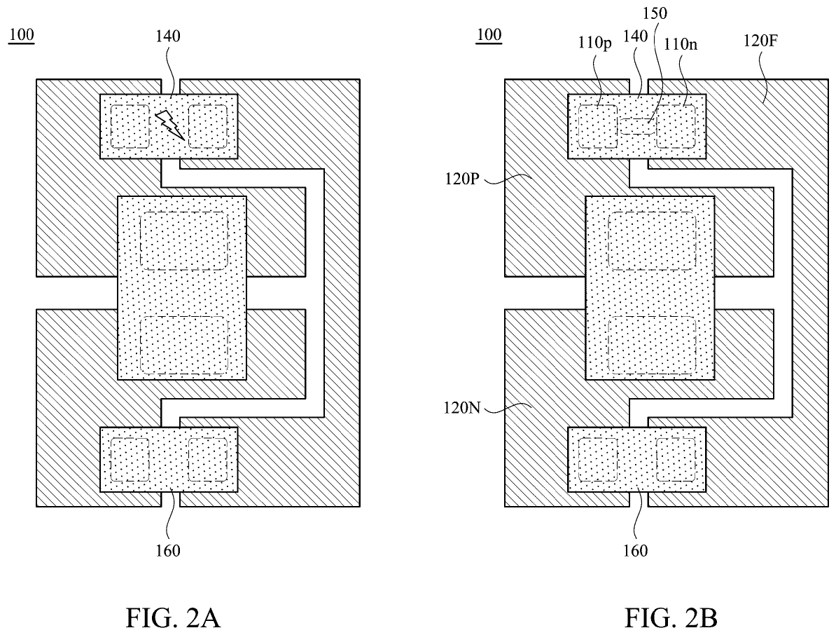

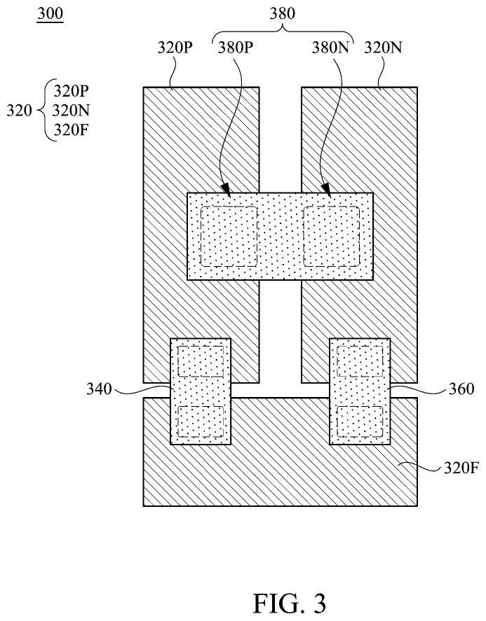

Referring to FIG. 2A and FIG. 2B, the FIG. 2A and FIG. 2B illustrate the schematically top views of the LED array substrate under two broken circuit states. FIG. 2A illustrates the LED array substrate 100 under an open circuit state, while FIG. 2B illustrates the LED array substrate 100 under a short circuit state. For instance, the LED component 140 of the LED array substrate 100 in FIG. 2A is a failed LED component (e.g., a broken LED component), so that the LED array substrate 100 is under an open circuit.

On the other hand, the LED component 140 and the LED component 160 of the LED array substrate 100 in FIG. 2B are not broken. However, the LED array substrate 100 in FIG. 2B further includes at least a soldering material 150. The soldering material 150 is disposed between at least one pair of pads and is connected to this pair of pads, and the pair of pads are electrically connected to each other through the soldering material 150. For instance, the soldering material 150 is disposed between the pad 110p and the pad 110n, and the pad 110p is electrically connected to the pad 110n through the soldering material 150. Thus, a short circuit is formed between the P-pole region 120P and the floating electrode region 120F of the substrate 120.

Referring to FIG. 1, in order to restore the LED array substrate 100 in FIG. 2A and FIG. 2B to the functional state, the LED array substrate 100 further includes a repairing LED component 180. The P-pole 180P of the repairing LED component 180 is connected to the P-pole region 120P of the substrate 120, while the N-pole 180N of the repairing LED component 180 is connected to the N-pole region 120N of the substrate 120. As a result, the P-pole region 120P of the substrate 120 is electrically connected to the N-pole region 120N of the substrate 120. That is, a connected path between the P-pole region 120P and the N-pole region 120N is formed, so as to restore the LED array substrate 100 to the functional state.

Although it is not denoted in figures, the LED array substrate 100 further includes a pair of pads (illustrated by dash lines) which are disposed between the substrate 120 and the repairing LED component 180. The P-pole 180P and the N-pole 180N of the repairing LED component 180 are electrically connected to the P-pole region 120P and the N-pole region 120N of the substrate 120 separately through this pair of pads.

It is worth mentioning, as shown in FIG. 1, the P-pole and the N-pole of the LED component are connected to each other in a first direction D1. Specifically, the P-pole 140P and the N-pole 140N of the LED component 140 are connected to each other in the first direction D1, while the P-pole 160P and the N-pole 160N of the LED component 160 are also connected to each other in the first direction D1. The P-pole 180P and the N-pole 180N of the repairing LED component 180 are connected to each other in a second direction D2, and the first direction D1 is orthogonal to the second direction D2. However, the disclosure is not limited to the embodiment, in other embodiments, the first direction D1 may not be orthogonal to (e.g., be parallel to) the second direction D2.

In some embodiments, in order to maintain the brightness after the repair, the light-emitting area of the repairing LED component 180 is an integer multiple of a light-emitting area of each of the LED components, and the light-emitting area of the repairing LED component 180 is at least double the light-emitting area of each of the LED components. For instance, the light-emitting area of the LED component 140 is equal to the light-emitting area of the LED component 160 in the embodiment of FIG. 1, while the light-emitting area of the repairing LED component 180 is equal to the light-emitting area of the LED component 140 adding up the light-emitting area of the LED component 160. As a result, the initial brightness of the LED array substrate 100 may be maintained by the repairing LED component 180 when the LED component 140 and the LED component 160 are failed.

In addition, a first gap g1 is located between the P-pole region 120P and the N-pole region 120N of the substrate 120, while a second gap g2 is separately located between the floating electrode region 120F and the P-pole region 120P and located between the floating electrode region 120F and the N-pole region 120N. In the embodiment, the first gap g1 is larger than the second gap g2. For instance, the first gap g1 which is located between the P-pole region 120P and the N-pole region 120N is between 10 μm and 20 μm, while the second gap g2 which is located between the floating electrode region 120F and the P-pole region 120P (or the N-pole region 120N) is between 5 μm and 15 μm. However, the disclosure is not limited to the embodiment, the first gap g1 may be smaller than or equal to the second gap g2 in other embodiments.

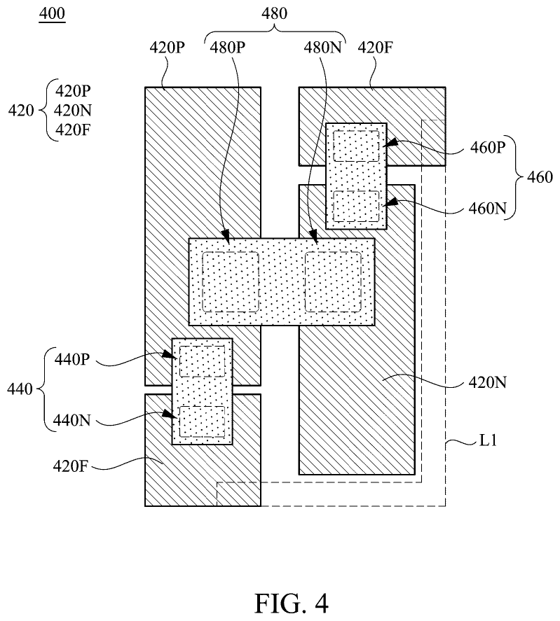

Referring to another embodiment shown in FIG. 3, the led array substrate 300 is similar to the LED array substrate 100. The LED array substrate 300 includes a substrate 320 and at least two LED components, the LED component 340 and the LED component 360. The difference between the LED array substrate 100 and the LED array substrate 300 is that the P-pole region 120P and the N-pole region 120N of the substrate 120 are in the shape of “L” and are symmetrical to each other, while the floating electrode region 120F is in the shape of symmetrical “C”. On the other hand, a P-pole region 320P, a N-pole region 320N and a floating electrode region 320F of the substrate 320 are in the shape of rectangle. However, in various embodiments of the disclosure, the shape of each region (including the P-pole region, the N-pole region and the floating electrode region) of the substrate is not limited to the aforementioned shapes. According to the practical requirement of the LED array substrate, the shapes of the regions may be varied.

It is worth mentioning, in some embodiments, the LED component 340 and the LED component 360 of the LED array substrate 300 may be substituted by one square type micro LED. Further, when the LED component 340 and the LED component 360 are failed, the LED array substrate 300 further includes a repairing LED component 380, and the P-pole 380P of the repairing LED component 380 is connected to the P-pole region 320P of the substrate 320, while the N-pole 380N of the repairing LED component 380 is connected to the N-pole region 320N of the substrate 320. As a result, the P-pole region 320P of the substrate 320 is electrically connected to the N-pole region 320N of the substrate 320, so as to restore the LED array substrate 300 to the functional state.

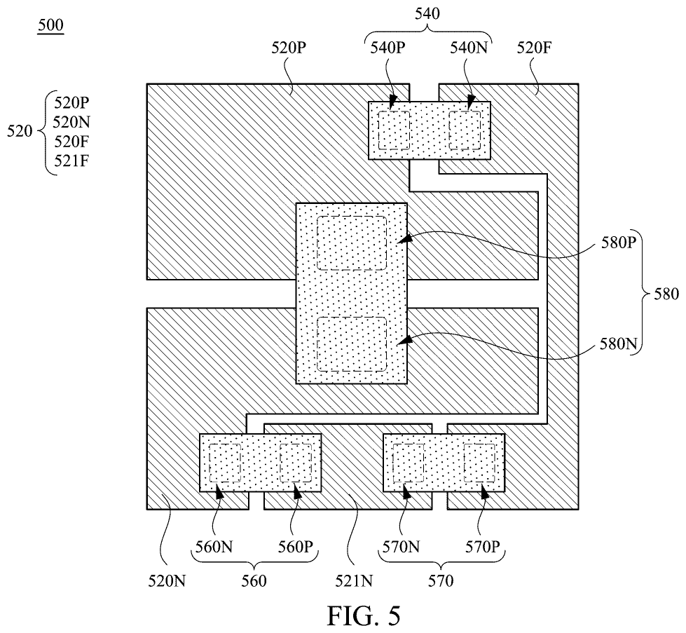

Referring to another embodiment shown in FIG. 4, the LED array substrate 400 is similar to the LED array substrate 100. The LED array substrate 400 includes a substrate 420 and at least two LED components, the LED component 440 and the LED component 460. However, the difference between the LED array substrate 100 and the LED array substrate 400 is that the quantity of the floating electrode regions 420F which are included in the substrate 420 is two. That is, the substrate 420 includes a P-pole region 420P, a N-pole region 420N and two floating electrode regions 420F.

The N-pole region 420N is spaced apart from the P-pole region 420P, while each floating electrode region 420F is spaced apart from the P-pole region 420P and the N-pole region 420N. It is worth mentioning, the two floating electrode regions 420F are disposed diagonally to each other. Specifically, one of the floating electrode regions 420F is adjacent to the P-pole region 420P and the N-pole region 420N, while the other one of the floating electrode regions 420F is also adjacent to the P-pole region 420P and the N-pole region 420N, but the floating electrode regions 420F are not adjacent to each other.

Thus, the P-pole 440P and the N-pole 440N of the LED component 440 are connected to the P-pole region 420P and one of the floating electrode regions 420F (the floating electrode region 420F at the bottom of FIG. 4) separately, while the P-pole 460P and the N-pole 460N of the LED component 460 are connected to the other one of the floating electrode regions 420F (the floating electrode region 420F at the top of FIG. 4) separately. It is worth mentioning, one of the floating electrode regions 420F in the embodiment may be electrically connected to the other one of the floating electrode regions 420F through an electrical circuit L1 (e.g., conductive layer or conductive wire). Thus, the LED component 440 and the LED component 460 are electrically connected to each other in series.

When the LED component 440 and the LED component 460 are failed, the LED array substrate 400 further includes a repairing LED component 480, and the P-pole 480P of the repairing LED component 480 is connected to the P-pole region 420P of the substrate 420, while the N-pole 480N of the repairing LED component 480 is connected to the N-pole region 420N of the substrate 420. As a result, the P-pole region 420P of the substrate 420 is electrically connected to the N-pole region 420N of the substrate 420, so as to restore the LED array substrate 400 to the functional state.

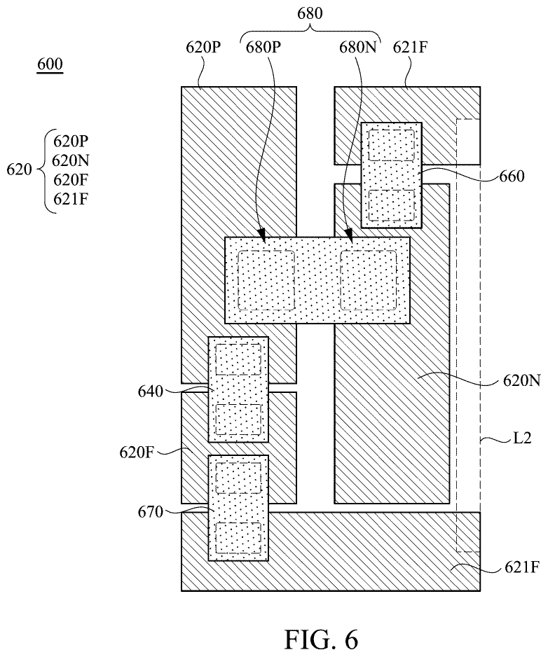

Referring to another embodiment shown in FIG. 5, the LED array substrate 500 is similar to the LED array substrate 400. The LED array substrate 500 includes a substrate 520, while the substrate 520 includes a P-pole region 520P, a N-pole region 520N, and two floating electrode regions, i.e., the floating electrode region 520F and the floating electrode region 521F. The difference between the LED array substrate 400 and the LED array substrate 500 is that the quantity of the LED components which are included in the LED array substrate 500 is three. That is, the LED array substrate 500 includes a LED component 540, a LED component 560 and a LED component 570. In the embodiment, the P-pole 570P and the N-pole 570N of the LED component 570 are connected to the floating electrode region 520F and the floating electrode region 521F separately.

Specifically, the P-pole 540P of the LED component 540 is connected to the P-pole region 520P of the substrate 520, while the N-pole 540N of the LED component 540 is connected to the floating electrode region 520F of the substrate 520. The P-pole 570P of the LED component 570 is connected to the floating electrode region 520F of the substrate 520, while the N-pole 570N is connected to the floating electrode region 521F of the substrate 520. The P-pole 560P of the LED component 560 is connected to the floating electrode region 521F of the substrate 520, while the N-pole 560N of the LED component 560 is connected to the N-pole region 520N of the substrate 520.

When the LED component 540, the LED component 560 and the LED component 570 are failed, the LED array substrate 500 further includes a repairing LED component 580, and the P-pole 580P of the repairing LED component 580 is connected to the P-pole region 520P of the substrate 520, while the N-pole 580N of the repairing LED component 580 is connected to the N-pole region 520N of the substrate 520. As a result, the P-pole region 520P of the substrate 520 is electrically connected to the N-pole region 520N of the substrate 520, so as to restore the LED array substrate 500 to the functional state.

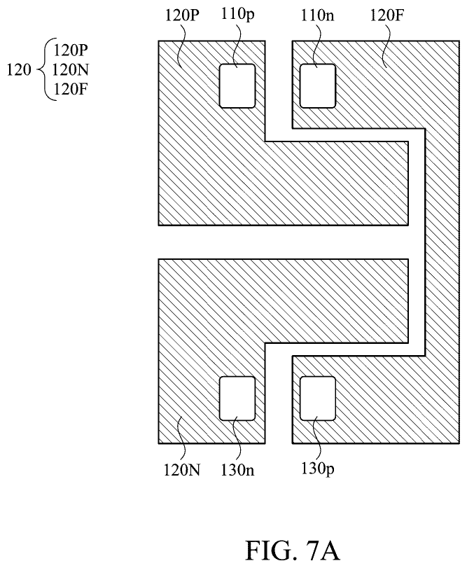

Referring to another embodiment shown in FIG. 6, the LED array substrate 600 is similar to the LED array substrate 500. The LED array substrate 600 includes a substrate 620, while the substrate 620 includes a P-pole region 620P, a N-pole region 620N, and two floating electrode regions, i.e., the floating electrode region 620F and the floating electrode region 621F. In addition, the LED array substrate 600 further includes a LED component 640, a LED component 660 and a LED component 670.

The difference between the LED array substrate 500 and the LED array substrate 600 is that the floating electrode region 621F of the LED array substrate 600 may be separated into two parts, and the two parts may be electrically connected to each other through an electrical circuit L2 (e.g., conductive layer or conductive wire).

When the LED component 640, the LED component 660 and the LED component 670 are failed, the LED array substrate 600 further includes a repairing LED component 680, and the P-pole 680P of the repairing LED component 680 is connected to the P-pole region 620P of the substrate 620, while the N-pole 680N of the repairing LED component 680 is connected to the N-pole region 620N of the substrate 620. As a result, the P-pole region 620P of the substrate 620 is electrically connected to the N-pole region 620N of the substrate 620, so as to restore the LED array substrate 600 to the functional state.

It is worth mentioning, in various embodiments of the disclosure, the quantities of the LED components and the floating electrode regions in the LED array substrate are not limited to the aforementioned embodiments. However, the quantity N1 of the LED components and the quantity N2 of the floating electrode regions in some embodiments satisfy the equation N2=N1−1.

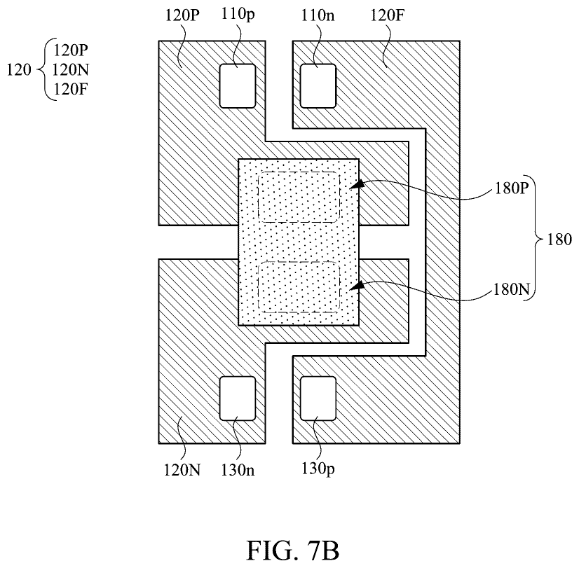

Referring to FIG. 2a (or FIG. 2b), FIG. 7a and FIG. 7b, FIG. 2a (or FIG. 2B), FIG. 7A and FIG. 7B illustrate sequent steps of the method of repairing the LED array substrate in accordance with at least one embodiment of present disclosure. Firstly, referring to FIG. 2A (or FIG. 2B), the failed LED array substrate 100 is provided. The failed LED array substrate 100 includes the substrate 120 and at least two LED components, the LED component 140 and the LED component 160. It is worth mentioning that at least one of the LED component 140 or the LED component 160 is failed.

Next, referring to FIG. 7A, the LED component 140 and the LED component 160 are removed. However, in the embodiment, two pairs of the pads disposed on the substrate 120, i.e., the pad 110p, the pad 110n, the pad 130p and the pad 130n, are retained on the substrate 120. Referring to FIG. 7B, the repairing LED component 180 is disposed on the substrate 120, while the P-pole 180P and the N-pole 180N of the repairing LED component 180 are connected to the P-pole region 120P and the N-pole region 120N of the substrate 120 separately.

It is worth mentioning, the aforementioned step that disposing the repairing LED component 180 on the substrate 120 is not limited to process after the LED component 140 and the LED component 160 are removed. In some embodiments, the repairing LED component 180 may be disposed on the substrate 120 before the LED component 140 and the LED component 160 are removed.

In conclusion, in at least one of the embodiment of the disclosure, at least one floating electrode region is disposed in the LED array substrate, and one pole (e.g., the P-pole) of the LED component is connected to the floating electrode region, while the other pole (e.g., the N-pole) of the LED component is connected to the P-pole region or the N-pole region. When the LED component is failed, a new LED component (i.e., the repairing LED component) may be disposed on the substrate directly, and the P-pole and the N-pole of the new LED component are connected to the P-pole region and the N-pole region of the substrate separately. Since the repairing LED component does not form a functional circuit through the floating electrode region, the condition without functional circuit between the floating electrode region and the P-pole region (or the floating electrode region and the N-pole region) will not affect the operation of the repairing LED component, so that the repairing LED component is able to illuminate.

In other words, no matter the failure of the LED array substrate is due to the short of inner components (e.g., the pads are connected to each other by contaminations) or due to the open circuit (e.g., the damage of LEDs), the method of repairing the LED array substrate is to disposing the repairing LED component on the substrate. The P-pole and the N-pole of the repairing LED component is connected to the P-pole region and the N-pole region of the substrate separately. Therefore, it is unnecessary to adopt different repairing methods for different failure causes. Thus, the checking step for determining the failure cause of the LED array substrate can be omitted, thereby being advantage to improve the efficiency of repairing the LED array substrate.

Although the embodiments of the present disclosure have been disclosed as above in the embodiments, they are not intended to limit the embodiments of the present disclosure. Any person having ordinary skill in the art can make various changes and modifications without departing from the spirit and the scope of the embodiments of the present disclosure. Therefore, the protection scope of the embodiments of the present disclosure should be determined according to the scope of the appended claims.

What is claimed is:

1. A light emitting diode array substrate, comprising:
a substrate comprising:
a P-pole region;
a N-pole region spaced apart from the P-pole region; and
at least one floating electrode region spaced apart from the P-pole region and the N-pole region; and
at least two LED components, wherein a P-pole and a N-pole of one of the LED components are connected to the P-pole region and the floating electrode region separately, and a P-pole and a N-pole of the other one of the LED components are connected to the floating electrode region and the N-pole region separately, wherein the LED components are connected to each other in series.

2. The light emitting diode array substrate of claim 1, further comprising:
a repairing LED component, wherein a P-pole of the repairing LED component is connected to the P-pole region of the substrate, and a N-pole of the repairing LED component is connected to the N-pole region of the substrate.

3. The light emitting diode array substrate of claim 2, wherein the P-pole and the N-pole of the LED components are connected to each other in a first direction, and the P-pole and the N-pole of the repairing LED component are connected to each other in a second direction, wherein the first direction is orthogonal to the second direction.

4. The light emitting diode array substrate of claim 2, wherein the P-pole and the N-pole of the LED components are connected to each other in a first direction, and the P-pole and the N-pole of the repairing LED component are connected to each other in a second direction, wherein the first direction is parallel to the second direction.

5. The light emitting diode array substrate of claim 2, wherein a light-emitting area of the repairing LED component is an integer multiple of a light-emitting area of each of the LED components, and the light-emitting area of the repairing LED component is at least double the light-emitting area of each of the LED components.

6. The light emitting diode array substrate of claim 2, further comprising:
a pair of pads disposed between the substrate and the repairing LED component, wherein the P-pole of the repairing LED component and the N-pole of the repairing LED component are electrically connected to the P-pole region and the N-pole region of the substrate separately through the pair of pads.

7. The light emitting diode array substrate of claim 1, further comprising:
at least two pairs of pads disposed between the LED components and the substrate, wherein one pair of pads are located at the P-pole region and the floating electrode region separately, and the other one pair of pads are located at the floating electrode region and the N-pole region separately.

8. The light emitting diode array substrate of claim 7, further comprising:
at least a soldering material disposed between at least one pair of pads, and the pair of pads are electrically connected to each other through the soldering material.

9. The light emitting diode array substrate of claim 1, wherein a quantity of the floating electrode region is two, and the P-pole and the N-pole of one of the LED components are connected to the P-pole region and one of the floating electrode regions separately, and the P-pole and the N-pole of the other one of the LED components are connected to the other one of the floating electrode regions and the N-pole region separately, wherein one of the floating electrode regions is electrically connected to the other one of the floating electrode regions.

10. The light emitting diode array substrate of claim 9, wherein a quantity of the floating electrode region is three, and the P-pole and the N-pole of at least one of the LED components are connected to two of the floating electrode regions separately.

11. The light emitting diode array substrate of claim 1, wherein a first gap is located between the P-pole region and the N-pole region of the substrate, and a second gap is separately located between the floating electrode region and the P-pole region and located between the floating electrode region and the N-pole region, wherein the first gap is larger than the second gap.

12. The light emitting diode array substrate of claim 11, wherein the first gap is between 10 μm and 20 μm, and the second gap is between 5 μm and 15 μm.

13. The light emitting diode array substrate of claim 1, wherein a quantity of the LED components is N1, and a quantity of the floating electrode regions is N2, wherein the quantity of the LED components and the quantity of the floating electrode regions satisfy the equation N2=N1−1.

14. The light emitting diode array substrate of claim 1, wherein the two LED components are substituted by one square type micro LED.

15. A method of repairing a light emitting diode array substrate, comprising:
providing a failed light emitting diode array substrate, and the light emitting diode array substrate comprises:
a substrate, comprising:
a P-pole region;
a N-pole region spaced apart from the P-pole region; and
at least one floating electrode region spaced apart from the P-pole region and the N-pole region; and
at least two LED components, wherein a P-pole and a N-pole of one of the LED components are connected to the P-pole region and the floating electrode region separately, and a P-pole and a N-pole of the other one of the LED components are connected to the floating electrode region and the N-pole region separately, wherein the LED components are connected to each other in series, and at least one of the LED components is failed;
removing the LED components; and
disposing a repairing LED component on the substrate, wherein a P-pole and a N-pole of the repairing LED component are connected to the P-pole region and the N-pole region of the substrate.
